(19) United States
(12) Patent Application Publication
(10) Pub. No.: US 2015/0017412 A1
(43) Pub. Date: Jan. 15, 2015

(54) STRENGTHENED GLASS

(71) Applicant: Nippon Electric Glass Co. Ltd., Shiga (JP)

(72) Inventors: Takashi Murata, Shiga (JP); Takako Tojyo, Shiga (JP); Masato Muguruma, Shiga (JP); Kosuke Kawamoto, Shiga (JP)

(21) Appl. No.: 14/379,564

(22) PCT Filed: Feb. 19, 2013
(86) PCT No.: PCT/JP2013/053941

§ 371 Date: Aug. 19, 2014

(30) Foreign Application Priority Data
Feb. 20, 2012 (JP) 2012-033749

(51) Int. Cl. C03C 3/093; C03B 27/012; H01L 31/0352; G06F 3/01; C03C 3/087; C03B 18/02; C03C 21/00

(52) U.S. Cl. CPC C03C 3/093; C03B 18/02; C03B 27/012; C03C 21/002; G06F 3/01; C03C 3/087; H01L 31/0352
USPC 428/220; 65/99.2; 65/114; 65/30.14; 428/410; 501/66; 501/69

(57) ABSTRACT

A tempered glass according to one embodiment of the present invention is a tempered glass having a compression stress layer in a surface thereof, the tempered glass including as a glass composition, in terms of mass %, 45 to 75% of SiO₂, 10 to 25% of Al₂O₃, 0 to 10% of B₂O₂, 0 to 8% of MgO, 0 to 20% of SrO+BaO, and 0 to 14% of Na₂O. Herein, the term “SrO+BaO” refers to the total amount of SrO and BaO.

### TECHNICAL FIELD

The present invention relates to a tempered glass, and more particularly, to a tempered glass suitable for, for example, a cover glass for a cellular phone, a digital camera, or a personal digital assistant (PDA), a substrate or cover glass for a solar cell such as a thin-film compound solar cell, or a substrate for a display such as a touch panel display.

### BACKGROUND ART

Devices such as a cellular phone, a digital camera, a PDA, a touch panel display, and a large-screen television tend to be more widely used.

A tempered glass produced by performing tempering treatment such as ion exchange treatment is used in each of those devices (see Patent Literature 1 and Non Patent Literature 1).

In conventional devices, there has been adopted a structure in which a touch panel sensor is formed on a display module and a tempered glass (protective member) is placed over the touch panel sensor.

Further, although small devices such as a cellular phone each have a size of 3 to 4 inches in most cases, tablet PCs and the like each have a size of 9 to 10 inches in most cases.

### CITATION LIST

### Patent Literature

Patent Literature 1: JP 2006-83045 A

### Non Patent Literature

Non Patent Literature 1: Tetsuro Izumitani et al., “New glass and physical properties thereof,” First edition, Management System Laboratory. Co., Ltd., Aug. 20, 1984, p. 451-498

### SUMMARY OF INVENTION

### Technical Problem

By the way, devices such as tablet PCs are required to have reduced mass and reduced total thickness in some cases.

Thus, in order to meet such requirement, a method involving forming a touch panel sensor on a tempered glass (protective member) has been being adopted. In this case, the tempered glass is required to, for example, (1) have a high mechanical strength, (2) have a liquidus viscosity suitable for, for example, a down-draw method such as an overflow down-draw method or a slit down-draw method, or a float method, in order to form a large amount of large glass to be tempered into a shape, (3) have a viscosity at high temperature suitable for being formed into a shape, and (4) have a low density.

Further, a touch panel is required to be capable of detecting not only information provided by finger input but also subtle information provided by pen input or the like. In this case, the touch panel needs to have a higher resolution capability of a signal to be detected. That is, a transparent conductive film formed on the touch panel needs to have a denser wiring pattern. As a result, many sensors are arranged on the wiring pattern, causing higher electrical resistance and thus leading to delayed electrical signal transmission, with the result that feeling of smooth operation of the tough panel is not achieved.

When a transparent conductive film such as an ITO film is formed on a tempered glass under high temperature, the crystallinity of the transparent conductive film increases, thus enabling reduced electrical resistance, but, when the tempered glass is subjected to thermal treatment under high temperature, there arise problems such as disappearance of a compression stress and thermal shrinkage of glass, which prevents precise pattering.

The present invention has been made in view of the above-mentioned circumstances. A technical object of the present invention is to produce a tempered glass which satisfies the above-mentioned required characteristics (1) to (4) and in which disappearance of a compression stress and thermal shrinkage are unlikely to occur even if the tempered glass is subjected to thermal treatment under high temperature.

### Solution to Problem

The inventors of the present invention have made various studies. As a result, the inventors have found that the above-mentioned technical object can be achieved by applying tempering treatment to a predetermined glass to be tempered, thereby yielding a tempered glass, and the finding is proposed as the present invention. That is, a tempered glass according to one embodiment of the present invention is a tempered glass having a compression stress layer in a surface thereof, the tempered glass comprising as a glass composition, in terms of mass %, 45 to 75% of SiO₂, 10 to 25% of Al₂O₃, 0 to 10% of B₂O₃, 0 to 8% of MgO, 0 to 20% of SrO+BaO, and 0 to 14% of Na₂O. Herein, the term “SrO+BaO” refers to the total amount of SrO and BaO.

Second, the tempered glass according to the one embodiment of the present invention is preferably a tempered glass having a compression stress layer in a surface thereof, the tempered glass comprising as a glass composition, in terms of mass %, 45 to 75% of SiO₂, 10 to 25% of Al₂O₃, 0 to 10% of B₂O₃, 0 to 4% of MgO, 0 to 20% of SrO+BaO, and 0 to 10% of Na₂O.

Third, the tempered glass according to the one embodiment of the present invention is preferably a tempered glass having a compression stress layer in a surface thereof, the tempered glass comprising as a glass composition, in terms of mass %, 45 to 63% of SiO₂, 10 to 25% of Al₂O₃, 0 to 10% of B₂O₃, 0 to 4% of MgO, 0.1 to 20% of SrO+BaO, and 1 to 10% of Na₂O.

Fourth, the tempered glass according to the one embodiment of the present invention is preferably a tempered glass having a compression stress layer in a surface thereof, the tempered glass comprising as a glass composition, in terms of mass %, 45 to 63% of SiO₂, 10 to 25% of Al₂O₃, 0 to 10% of B₂O₃, 0 to 4% of MgO, 0.1 to 20% of SrO+BaO, and 1 to 10% of Na₂O and having a mass ratio (MgO+CaO)/(SrO+BaO) of from 0.1 to 1.5. Herein, the term “MgO+CaO” refers to the total amount of MgO and CaO.

Fifth, the tempered glass according to the one embodiment of the present invention is preferably a tempered glass having a compression stress layer in a surface thereof, the tempered glass comprising as a glass composition, in terms of mass %, 45 to 63% of SiO₂, 10 to 25% of Al₂O₃, 0 to 10% of B₂O₃, 0 to 3% of MgO, 0.1 to 15% of CaO, 0.1 to 13% of SrO, 0.1 to 20% of SrO+BaO, and 1 to 8% of Na₂O and having a mass ratio (MgO+CaO)/(SrO+BaO) of from 0.1 to 1.0.

Sixth, the tempered glass according to the one embodiment of the present invention is preferably a tempered glass having a compression stress layer in a surface thereof, the tempered glass comprising as a glass composition, in terms of mass %, 45 to 63% of SiO₂, 10 to 25% of Al₂O₃, 0 to 10% of B₂O₃, O to less than 2% of MgO, 2 to 15% of CaO, 5 to 13% of SrO, 0.1 to 8% of BaO, 5.1 to 20% of SrO+BaO, and 1 to 8% of Na₂O and having a mass ratio (MgO+CaO)/(SrO+BaO) of from 0.1 to 0.8.

Seventh, the tempered glass according to the one embodiment of the present invention is preferably a tempered glass having a compression stress layer in a surface thereof, the tempered glass comprising as a glass composition, in terms of mass %, 45 to 63% of SiO₂, 12 to 25% of Al₂O₃, 0 to 10% of B₂O₃, O to less than 2% of MgO, 2 to 15% of CaO, 8 to 13% of SrO, 2 to 8% of BaO, 10 to 20% of SrO+BaO, and 1 to 8% of Na₂O and having a mass ratio (MgO+CaO)/(SrO+BaO) of from 0.1 to 0.5.

Eighth, in the tempered glass according to the one embodiment of the present invention, it is preferred that a compression stress value of the compression stress layer be 300 MPa or more, and a thickness (stress depth) of the compression stress layer be 5 μm or more. Herein, the “compression stress value of the compression stress layer” and the “thickness of the compression stress layer” can be calculated by observing the number of interference fringes and each interval between the interference fringes, with a surface stress meter.

Ninth, it is preferred that the tempered glass according to the one embodiment of the present invention have an internal tensile stress of 50 MPa or less. Herein, the “internal tensile stress” can be calculated from Equation 1 described below. Note that the thickness in Equation 1 corresponds to a sheet thickness in the case of a flat sheet shape.

Internal tensile stress=(compression stress value×stress depth)/(thickness−stress depth×2) (Equation 1)

Tenth, it is preferred that the tempered glass according to the one embodiment of the present invention have a thermal expansion coefficient of from 50×10⁻⁷ to 100×10⁻⁷/° C. Herein, the term “thermal expansion coefficient” refers to a value obtained through measurement of an average thermal expansion coefficient in the temperature range of from 30 to 380° C. with a dilatometer.

Eleventh, it is preferred that the tempered glass according to the one embodiment of the present invention have a strain point of 550° C. or more. Herein, the term “strain point” refers to a value obtained through measurement based on a method of ASTM C336.

Twelfth, it is preferred that the tempered glass according to the one embodiment of the present invention have a temperature at a viscosity at high temperature of 10^{2.5} dPa·s of 1,550° C. or less. Herein, the term “temperature at a viscosity at high temperature of 10^{2.5} dPa·s” refers to a value obtained through measurement by a platinum sphere pull up method.

Thirteenth, it is preferred that the tempered glass according to the one embodiment of the present invention have a liquidus temperature of 1,200° C. or less. Herein, the term “liquidus temperature” refers to a temperature at which crystals of glass are deposited after glass is pulverized and glass powder that passes through a standard 30-mesh sieve (sieve opening: 500 μm) and remains on a 50-mesh sieve (sieve opening: 300 μm) is placed in a platinum boat and then kept for 24 hours in a gradient heating furnace.

Fourteenth, it is preferred that the tempered glass according to the one embodiment of the present invention have a liquidus viscosity of 10^{3.0} dPa·s or more. Herein, the term “liquidus viscosity” refers to a value obtained through measurement of a viscosity of glass at the liquidus temperature by a platinum sphere pull up method.

Fifteenth, it is preferred that the tempered glass according to the one embodiment of the present invention be used for a substrate for a solar cell.

Sixteenth, it is preferred that the tempered glass according to the one embodiment of the present invention be used for a substrate for a thin-film compound solar cell.

Seventeenth, it is preferred that the tempered glass according to the one embodiment of the present invention be used for a substrate for a display.

Eighteenth, it is preferred that the tempered glass according to the one embodiment of the present invention be formed into a flat sheet shape by a float method.

Nineteenth, it is preferred that the tempered glass according to the one embodiment of the present invention be manufactured by being cooled at an average cooling rate of 200° C./min or less in a temperature region from (annealing point+30° C.) to (strain point−70° C.). Herein, the term “annealing point” refers to a value obtained through measurement based on a method of ASTM C336.

Twentieth, a glass to be tempered according to one embodiment of the present invention comprises as a glass composition, in terms of mass %, 45 to 75% of SiO₂, 10 to 25% of Al₂O₃, 0 to 10% of B₂O₃, 0 to 8% of MgO, 0 to 20% of SrO+BaO, and 0 to 14% of Na₂O.

Twenty-first, it is preferred that the glass to be tempered according to the one embodiment of the present invention have a thickness of 2 mm or less and have a thermal shrinkage amount of 250 ppm or less when the glass to be tempered is subjected to thermal treatment under the conditions of 500° C. for 1 hour after being subjected to tempering treatment involving immersion in KNO₃ at 460° C. for 6 hours. Herein, the “thermal shrinkage amount” can be calculated in accordance with, for example, the following procedure. As illustrated in FIG. 1, linear markings 2 are drawn at two sites on a glass 1 having a flat sheet shape and a distance l₀ between the markings 2 is then measured. Next, the glass 1 is folded vertically with respect to the markings 2, thereby dividing the glass 1 into two sample pieces. Further, after tempering treatment is applied to only one of the sample pieces, a tempered sample piece 1a and a non-tempered sample piece 1b are lined up, followed by fixing of the both with an adhesive tape, and marking shifts ΔL₁ and ΔL₂ are measured. In the measurement, in the case where the positions of the markings 2 of the tempered sample piece la are located inside the positions of the markings 2 of the non-tempered sample piece 1b, ΔL₁ and ΔL₂ are represented as positive values, and a volume change amount S1 is calculated by using Equation 2 described below. Note that the tempering treatment is carried out by immersing a sample piece in KNO₃ at 460° C. for 6 hours. Subsequently, thermal treatment is applied only to the tempered glass 1. The thermal treatment is carried out under the conditions of a temperature rise to 500° C. at +3° C./min, maintenance of the temperature of 500° C. for 1 hour, and a temperature fall to room temperature at −3° C./min. After that, the thermally treated sample piece 1a and the non-thermally treated (and non-tempered) sample piece 1b are lined up, followed by fixing of the both with an adhesive tape, and marking shifts ΔL₁ and ΔL₂ are measured. In the measurement, in the case where the positions of the markings 2 of the thermally treated sample piece 1a are located inside the positions of the markings 2 of the non-thermally treated sample piece 1b, ΔL₁ and ΔL₂ are represented as positive values, and a volume change amount S2 is calculated by using Equation 2 described below. Finally, the thermal shrinkage amount S of the glass to be tempered is calculated by using Equation 3.

S=[{ΔL₁ (μm)+ΔL₂ (μm)}]×10³]/lₒ (mm) (Equation 2)

S=S2−S1 (Equation 3)

### BRIEF DESCRIPTION OF DRAWINGS

FIG. 1 is a schematic explanatory diagram illustrating a measurement method for a thermal shrinkage amount.

### DESCRIPTION OF EMBODIMENTS

A tempered glass according to an embodiment of the present invention has a compression stress layer in a surface thereof and comprises as a glass composition, in terms of mass %, 45 to 75% of SiO₂, 10 to 25% of Al₂O₂, 0 to 10% of B₂O₃, 0 to 8% of MgO, 0 to 14% of Na₂O, and 0 to 20% of SrO+BaO.

A physical tempering method may be chosen as a method of forming the compression stress layer in the surface of the glass, but it is more preferred that a chemical tempering method be chosen. The chemical tempering method is a method comprising introducing alkali ions each having a large ion radius into the vicinity of a surface of glass by performing ion exchange at a temperature equal to or lower than the strain point of the glass. When the chemical tempering method is used to form the compression stress layer, a desired compression stress layer can be formed even if the glass has a thin thickness. In addition, even when the compression stress layer is formed by the chemical tempering method and then the resultant tempered glass is cut, the tempered glass does not easily break unlike tempered glass produced by applying a physical tempering method such as an air cooling tempering method.

The ion exchange treatment can be performed by, for example, immersing glass in a KNO₃ molten salt at 400 to 550° C. for to 24 hours. As conditions for the ion exchange, optimum conditions may be selected in view of, for example, the viscosity characteristics, applications, thickness, and internal tensile stress of glass. Note that when the ion exchange of K ions in the KNO₃ molten salt with Na components in the glass is performed, it is possible to form efficiently the compression stress layer.

The reasons why the content range of each component in the glass composition in the tempered glass of this embodiment has been restricted as mentioned above are described below.

SiO₂ is a component that forms a network of glass. The content of SiO₂ is 45 to 75%, preferably 45 to 70%, more preferably 45 to 63%, still more preferably 48 to 60%, most preferably 50 to 58%. When the content of SiO₂ is too large, melting and forming become difficult, and a thermal expansion coefficient becomes too low, with the result that matching of the thermal expansion coefficient with those of peripheral materials becomes difficult. On the other hand, when the content of SiO₂ is too small, vitrification becomes difficult, and the thermal expansion coefficient becomes too high, with the result that thermal shock resistance is liable to lower.

Al₂O₃ is a component that enhances ion exchange performance, and is a component that enhances a strain point and a Young's modulus. The content of Al₂O₃ is 10 to 25%. When the content of Al₂O₃ is too large, a devitrified crystal is liable to deposit in the glass and forming of the glass becomes difficult. Further, when the content of Al₂O₃ is too large, the thermal expansion coefficient becomes too low, with the result that matching of the thermal expansion coefficient with those of peripheral materials becomes difficult, and its viscosity at high temperature rises, with the result that it becomes difficult to melt the glass. On the other hand, when the content of Al₂O₃ is too small, ion exchange performance may not be sufficiently exhibited. The lower limit range of Al₂O₃ is suitably 11% or more, 12% or more, and the upper limit range of Al₂O₃ is suitably 22% or less, 20% or less, 18% or less, 16% or less, 15% or less.

B₂O₃ is a component that has an effect of lowering the viscosity at high temperature and density, and has effects of stabilizing glass so that a crystal may be unlikely to be precipitated, and lowering the liquidus temperature. The content of B₂O₃ is 0 to 10%, preferably 0 to 5%, more preferably 0 to 3%, still more preferably 0 to 1%, and it is desirable that the glass be substantially free of B₂O₃. Herein, the phrase “substantially free of B₂O₃” refers to the case where the content of B₂O₃ in the glass composition is less than 0.1 mass %. When the content of B₂O₃ is too large, the strain point lowers, ion exchange treatment causes weathering to occur in a surface of the glass, the water resistance deteriorates, and the thickness of the compression stress layer tends to be smaller.

MgO is a component that lowers the viscosity at high temperature to enhance meltability and formability, or to enhance the strain point and the Young's modulus, and is a component that shows a particularly high effect of improving the ion exchange performance, among alkaline earth metal oxides. The content of MgO is 0 to 8%, preferably 0 to 4%, more preferably 0 to 3%, still more preferably 0 to 2%, particularly preferably 0.01 to 1%, most preferably 0.05 to 1%. However, when the content of MgO becomes too large, the density and the thermal expansion coefficient increase improperly, and the glass is liable to be devitrified.

Na₂O is an ion exchange component, is a component that lowers the viscosity at high temperature to enhance the meltability and the formability, and is a component that improves devitrification resistance. The content of Na₂O is 0 to 14%, preferably 0 to 10%, more preferably 1 to 10%, still more preferably 1 to 8%, still more preferably 2 to 8%, particularly preferably 3 to less than 7%, most preferably 4 to 6.5%. When the content of Na₂O is too large, the thermal expansion coefficient becomes too high, and hence, the thermal shock resistance lowers, and matching of the thermal expansion coefficient with those of peripheral materials becomes difficult. Further, when the content of Na₂O is too large, the strain point lowers excessively, and the component balance in the glass composition is impaired, with the result that the devitrification resistance tends to deteriorate rather than improve. On the other hand, when the content of Na₂O is too small, the meltability deteriorates, the thermal expansion coefficient becomes too low, and the ion exchange performance is liable to deteriorate.

SrO is a component that reduces the viscosity at high temperature to increase the meltability and formability, and increases the strain point and Young's modulus. However, when the content of SrO is too large, the ion exchange performance tends to deteriorate, the density and thermal expansion coefficient improperly increase, and the glass is liable to devitrify. Thus, the content of SrO is preferably 0 to 15%, 0.1 to 13%, 2 to 13%, 5 to 13%, 7 to 13%, 8 to 13%, particularly preferably 9 to 12%.

BaO is a component that reduces the viscosity at high temperature to increase the meltability and formability, and increases the strain point and Young's modulus. However, when the content of BaO is too large, the ion exchange performance tends to deteriorate, the density and thermal expansion coefficient improperly increase, and the glass is liable to devitrify. Thus, the content of BaO is preferably 0 to 12%, 0.1 to 10%, 0.1 to 9%, 0.1 to 8%, 1 to 8%, 2 to 8%, particularly preferably 3 to 8%.

SrO+BaO is a component that reduces the viscosity at high temperature to increase the meltability and formability, and increases the strain point and Young's modulus. The content of SrO+BaO is 0 to 20%. When the content of SrO+BaO is large, the ion exchange performance tends to deteriorate, the density and thermal expansion coefficient increase, and the glass is liable to devitrify. However, when the content of SrO+BaO is small, the above-mentioned effects are poorly provided. The content range of SrO+BaO is suitably 0.1 to 20%, 2 to 20%, 5.1 to 20%, 10 to 20%, 12 to 18%, particularly suitably 13 to 17%.

In addition to the components described above, the following components may be added.

CaO is a component that reduces the viscosity at high temperature to increase the meltability and formability, and increases the strain point and Young's modulus, is a component that shows a particularly high effect of enhancing the ion exchange performance among alkaline earth metal oxides, and is also a component that increases the denitrification resistance. The content of CaO is preferably 0.1 to 15%, 1 to 15%, 2 to 11%, 3 to 9%, particularly preferably 4 to 7%. When the content of CaO is too large, the density and thermal expansion coefficient improperly increase, and the component balance in the glass composition is impaired, with the result that the glass is liable to denitrify and the ion exchange performance tends to deteriorate.

A mass ratio (MgO+CaO)/(SrO+BaO) is preferably 0 to 1. When the mass ratio (MgO+CaO)/(SrO+BaO) is restricted within a proper range, a high liquidus viscosity is easily maintained while a high strain point is maintained. The lower limit range of the mass ratio (MgO+CaO)/(SrO+BaO) is suitably 0.1 or more, 0.2 or more, 0.3 or more, particularly suitably 0.4 or more, and the upper limit range thereof is suitably 0.9 or less, 0.8 or less, 0.7 or less, particularly suitably 0.6 or less.

MgO+CaO+SrO+BaO is a component that reduces the viscosity at high temperature without reducing the strain point excessively. When the content thereof is too large, the density and thermal expansion coefficient improperly increase, the denitrification resistance is liable to deteriorate, and the ion exchange performance is liable to deteriorate. Thus, the content of MgO+CaO+SrO+BaO is preferably 10 to 30%, 13 to 27%, 15 to 25%, 17 to 23%, 18 to 22%, particularly preferably 19 to 21%. Note that the term “MgO+CaO+SrO+BaO” refers to the total amount of MgO, CaO, SrO, and BaO.

Li₂O is an ion exchange component and is a component that reduces the viscosity at high temperature to increase the meltability and formability. Further, Li₂O is a component that increases the Young's modulus and a component that shows a high effect of increasing the compression stress value among alkali metal oxides. However, when the content of Li₂O is too large, the liquidus viscosity lowers, the glass is liable to denitrify, and the thermal expansion coefficient becomes too high, with the result that the thermal shock resistance deteriorates and it becomes difficult to match the thermal expansion coefficient with those of peripheral materials. In addition, when the content of Li₂O is too large, the viscosity at low temperature reduces excessively, and the stress relaxation is liable to occur, with the result that the compression stress value lowers rather than increases in some cases. Thus, the content of Li₂O is preferably 0 to 10%, 0 to 5%, 0 to 1%, particularly preferably 0 to 0.5%, and it is desirable that the glass be substantially free of Li₂O. Herein, the phrase “substantially free of Li₂O” refers to the case where the content of Li₂O in the glass composition is less than 0.1%.

K₂O is a component that promotes ion exchange and is a component that shows a high effect of increasing the thickness of the compression stress layer among alkali metal oxides. In addition, K₂O is a component that reduces the viscosity at high temperature to increase the meltability and formability and is also a component that improves the devitrification resistance. However, when the content of K₂O is too large, the thermal expansion coefficient becomes improperly high, the thermal shock resistance deteriorates, and it becomes difficult to match the thermal expansion coefficient with those of peripheral materials. Further, when the content of K₂O is too large, the strain point lowers excessively, and the component balance in the glass composition is impaired, with the result that the devitrification resistance tends to deteriorate rather than improve. In view of the above-mentioned circumstances, the content of K₂O is preferably 0 to 15%, 0.5 to 13%, 2 to 10%, 3 to 9%, particularly preferably 3 to 7%.

Li₂O+Na₂O+K₂O is an ion exchange component and is a component that reduces the viscosity at high temperature to increase the meltability and formability. When the content of Li₂O+Na₂O+K₂O is too large, the glass is liable to denitrify, and the thermal expansion coefficient becomes too high, with the result that the thermal shock resistance deteriorates and it becomes difficult to match the thermal expansion coefficient with those of peripheral materials. Moreover, when the content of Li₂O+Na₂O+K₂O is too large, the strain point lowers excessively, with the result that a high compression stress value is difficult to be achieved in some cases, and when thermal treatment is applied to the glass at high temperature, the compression stress of the glass is liable to disappear. In addition, when the content of Li₂O+Na₂O+K₂O is too large, the viscosity at around the liquidus temperature reduces, with the result that it is difficult to attain a high liquidus viscosity in some cases. Thus, the content of Li₂O+Na₂O+K₂O is preferably 20% or less, 18% or less, 15% or less, 13% or less, particularly preferably 12% or less. On the other hand, when the content of Li₂O+Na₂O+K₂O is too small, the ion exchange performance and meltability are liable to deteriorate. Thus, the content of Li₂O+Na₂O+K₂O is preferably 3% or more, 5% or more, 7% or more, 8% or more, particularly preferably 9% or more. Note that the term “Li₂O+Na₂O+K₂O” refers to the total amount of Li₂O, Na₂O, and K₂O.

ZrO₂ is a component that remarkably enhances the ion exchange performance and increases the viscosity around the liquidus viscosity and the strain point. The content of ZrO₂ is preferably 0 to 15%, 0 to 10%, 0.001 to 10%, 0.1 to 9%, 2 to 8%, particularly preferably 2.5 to 5%. When the content of ZrO₂ is too large, the denitrification resistance extremely deteriorates in some cases.

P₂O₅ is a component that enhances the ion exchange performance and a component that shows a particularly high effect of increasing the thickness of the compression stress layer. The content of P₂O₅ is preferably 10% or less, 8% or less, 6% or less, 4% or less, 2% or less, particularly preferably 0.5% or less. When the content of P₂O₅ is too large, phase separation occurs in the glass and the water resistance is liable to deteriorate.

Fe₂O₃ is a component that is comprised as an impurity in raw materials and is a component that acts as a fining agent. The content of Fe₂O₃ is preferably 0 to 2%, 0 to 1%, 0 to 0.5%, 0 to 0.1%, particularly preferably 0.001 to 0.05%. When the content of Fe₂O₃ is too large, the glass is liable to be colored and to devitrify. Note that, in order to reduce the content of Fe₂O₃ extremely, a high-purity raw material needs to be used, which significantly increases the batch cost.

TiO₂ is a component that enhances the ion exchange performance and is a component that reduces the viscosity at high temperature. However, when the content thereof is too large, the glass is liable to be colored and to devitrify. The content of TiO₂ is preferably 0 to 5%, 0 to 4%, 0 to 1%, particularly preferably 0 to 0.1%, and it is desirable that the glass be substantially free of TiO₂. Herein, the phrase “substantially free of TiO₂” refers to the case where the content of TiO₂ in the glass composition is 0.01% or less.

ZnO is a component that enhances the ion exchange performance and is a component that shows a particularly high effect of increasing the compression stress value. Further, ZnO is a component that reduces the viscosity at high temperature without reducing the viscosity at low temperature. When the content of ZnO is too large, phase separation occurs in the glass, the devitrification resistance deteriorates, the density improperly increases, and the thickness of the compression stress layer tends to decrease. Thus, the content of ZnO is preferably 0 to 6%, 0 to 5%, 0 to 3%, particularly preferably 0 to 1%, and it is desirable that the glass be substantially free of ZnO. Herein, the phrase “substantially free of ZnO” refers to the case where the content of ZnO in the glass composition is 0.1% or less.

It is possible to use, as a fining agent, one kind or two or more kinds selected from the group consisting of SnO₂, CeO₂, Cl, and SO₃. The total content of these components is preferably 0 to 3%, 0.001 to 1%, 0.01 to 0.5%, particularly preferably 0.05 to 0.4%. When the content of these components is too large, the devitrification resistance is liable to deteriorate. Among these components, SnO₂ and SO₃ are particularly preferably used from the viewpoint of a fining effect. The content of SnO₂ is preferably 0 to 1%, 0.01 to 0.5%, particularly preferably 0.05 to 0.4%. The content of SO₃ is preferably 0 to 1%, 0.01 to 0.5%, particularly preferably 0.03 to 0.4%.

Rare earth oxides such as Nb₂O₅ and La₂O₃ are components that increase the Young's modulus. However, the costs of the raw materials themselves thereof are high, and when the rare earth oxides are comprised in a large amount, the devitrification resistance is liable to deteriorate. Thus, the total content of the rare earth oxides is preferably 3% or less, 2% or less, 1% or less, 0.5% or less, particularly preferably 0.1% or less.

Transition metal oxides such as Co and Ni are components that cause the intense coloration of glass, thereby reducing the transmittance of the glass. When the total content of the transition metal oxides is too large in a tempered glass used for a solar cell, the photoelectric conversion efficiency of the solar cell is particularly liable to deteriorate. Thus, it is desirable that the use amounts of glass raw materials (including cullet) be adjusted so that the total content of the transition metal oxides is preferably 0.5% or less, 0.1% or less, particularly preferably 0.05% or less.

It is desirable that the glass be substantially free of As₂O₃, Sb₂O₃, PbO, Bi₂O₃, and F, because they are components that may adversely affect the environment. Herein, the phrase “substantially free of As₂O₃” refers to the case where the content of As₂O₃ in the glass composition is less than 0.01%. The phrase “substantially free of Sb₂O₃” refers to the case where the content of Sb₂O₃ in the glass composition is less than 0.01%. The phrase “substantially free of PbO” refers to the case where the content of PbO in the glass composition is less than 0.1%. The phrase “substantially free of Bi₂O₃” refers to the case where the content of Bi₂O₃ in the glass composition is less than 0.1%. The phrase “substantially free of F” refers to the case where the content of F in the glass composition is less than 0.1%.

In addition to the above-mentioned components, other components may be added, for example, up to 10%, in particular, up to 5%.

The tempered glass of this embodiment has a thermal expansion coefficient of preferably 50×10⁻⁷ to 100×10⁻⁷/° C., 70×10⁻⁷ to 100×10⁻⁷/° C., 75×10⁻⁷ to 95×10⁻⁷/° C., particularly preferably 80×10⁻⁷ to 90×10⁻⁷/° C. With this, the rate of breakage caused by rapid temperature change can be reduced at the time of tempering treatment, and it becomes easy to match the thermal expansion coefficient with those of members such as an ITO film, thus easily preventing failures such as film peeling. Note that the thermal expansion coefficient can be increased by increasing the content of an alkali metal oxide or an alkaline earth metal oxide in the glass composition, and in contrast, the thermal expansion coefficient can be decreased by reducing the content of an alkali metal oxide or an alkaline earth metal oxide in the glass composition.

The tempered glass of this embodiment has a density of preferably 3 g/cm³ or less, 2.9 g/cm³ or less, particularly preferably 2.85 g/cm³ or less. As the density becomes smaller, the weight of the tempered glass can be reduced more. Note that the density can be decreased by increasing the content of SiO₂, P₂Oₛ, or B₂O₃ in the glass composition or reducing the content of an alkali metal oxide, an alkaline earth metal oxide, ZnO, ZrO₂, or TiO₂ in the glass composition. Herein, the term “density” refers to a value obtained through measurement by the well-known Archimedes method.

The tempered glass of this embodiment has a strain point of preferably 580° C. or more, 600° C. or more, 610° C. or more, particularly preferably 620° C. or more. The strain point is a characteristic serving as an index for heat resistance. As the strain point becomes higher, the disappearance of the compression stress is more unlikely to occur even when the tempered glass is subjected to thermal treatment at high temperature and the tempered glass can more easily maintain its mechanical strength. Further, as the strain point becomes higher, the tempered glass resists thermal shrinkage more even if the tempered glass is subjected to thermal treatment at high temperature. In addition, as the strain point becomes higher, stress relaxation is more unlikely to occur at the time of ion exchange, and hence a higher compression stress value can be provided. Note that the strain point can be increased by reducing the content of an alkali metal oxide in the glass composition or increasing the content of an alkaline earth metal oxide, Al₂O₃, ZrO₂, or P₂O₅ in the glass composition.

The tempered glass of this embodiment has a temperature at a viscosity at high temperature of 10^{2.5} dPa·s of preferably 1,600° C. or less, 1,570° C. or less, 1,530° C. or less, 1,500° C. or less, 1,480° C. or less, particularly preferably 1,450° C. or less. The temperature at a viscosity at high temperature of 10^{2.5} dPa·s corresponds to the melting temperature of glass. As the temperature at a viscosity at high temperature of 10^{2.5} dPa·s becomes lower, the glass can be melted at lower temperature. Further, as the temperature at a viscosity at high temperature of 10^{2.5} dPa·s becomes lower, a smaller burden is given to glass production equipment such as a melting furnace, and the bubble quality of the glass can be enhanced. As a result, the tempered glass can be produced at lower cost. Note that the temperature at a viscosity at high temperature of 10^{2.5} dPa·s can be decreased by increasing the content of an alkali metal oxide, an alkaline earth metal oxide, ZnO, B₂O₃, or TiO₂ or reducing the content of SiO₂ or Al₂O₃.

The tempered glass of this embodiment has a liquidus temperature of preferably 1,200° C. or less, 1,180° C. or less, 1,150° C. or less, 1,120° C. or less, 1,100° C. or less, particularly preferably 1080° C. or less. As the liquidus temperature becomes lower, the devitrification resistance and formability are improved more. Note that the liquidus temperature can be decreased by increasing the content of Na₂O, K₂O, or B₂O₃ in the glass composition or by reducing the content of Al₂O₃, Li₂O, MgO, ZnO, TiO₂, or ZrO₂ in the glass composition.

The tempered glass of this embodiment has a liquidus viscosity of preferably 10^{4.0} dPa·s or more, 10^{4.2} dPa·s or more, 10^{4.3} dPa·s or more, 10^{4.5} dPa·s or more, 10^{4.7} dPa·s or more, particularly preferably 10^{4.9} dPa·s or more. As the liquidus viscosity becomes higher, the devitrification resistance and formability are improved more. Note that the liquidus viscosity can be increased by increasing the content of Na₂O or K₂O in the glass composition or by reducing the content of Al₂O₃, Li₂O, MgO, ZnO, TiO₂, or ZrO₂ in the glass composition.

The compression stress value of the compression stress layer in the tempered glass of this embodiment is preferably 300 MPa or more, 400 MPa or more, 500 MPa or more, particularly preferably 600 MPa or more. As the compression stress value of the compression stress layer becomes larger, the mechanical strength of the tempered glass increases. On the other hand, when an extremely large compression stress is formed in the tempered glass, micro cracks are generated in the surface thereof, with the result that the mechanical strength of the tempered glass may reduce rather than increases. Further, when an extremely large compression stress is formed in the tempered glass, an internal tensile stress may extremely increase. Thus, the compression stress value of the compression stress layer is preferably 1,300 MPa or less, 1,000 MPa or less, 900 MPa or less, 800 MPa or less, particularly preferably 700 MPa or less. Note that the compression stress value of the compression stress layer can be increased by increasing the content of Al₂O₃, TiO₂, ZrO₂, MgO, or ZnO in the glass composition or reducing the content of SrO or BaO in the glass composition. Further, the compression stress value of the compression stress layer can be increased by shortening an ion-exchange time or lowering an ion-exchange temperature.

The thickness of the compression stress layer in the tempered glass of this embodiment is preferably 5 μm or more, 10 μm or more, 15 μm or more, 20 μm or more, particularly preferably 30 μm or more. As the thickness of the compression stress layer becomes larger, the tempered glass is more unlikely to break even when the tempered glass has a deep flaw. On the other hand, when the compression stress layer has too large a thickness, the tempered glass is more difficult to be cut and processed. Thus, the thickness of the compression stress layer is preferably 100 μm or less, 80 μm or less, 60 μm or less, 50 μm or less, particularly preferably 40 μm or less. Note that the thickness of the compression stress layer can be increased by increasing the content of K₂O or P₂O₅ in the glass composition or reducing the content of SrO or BaO in the glass composition. Further, the thickness of the compression stress layer can be increased by lengthening an ion-exchange time or raising an ion-exchange temperature. Note that, in order to form the above-mentioned compression stress layer, ion exchange treatment is preferably performed in a KNO₃ molten salt at 400 to 550° C. for 2 to 24 hours, in particular, 10 to 18 hours.

The tempered glass of this embodiment has an internal tensile stress of preferably 50 MPa or less, 40 MPa or less, 30 MPa or less, particularly preferably 25 MPa or less. As the internal tensile stress becomes smaller, it is more unlikely that the tempered glass is broken by defects inside the tempered glass, and a cutting failure is more unlikely to occur when the tempered glass is cut. However, when the tempered glass has an extremely small internal tensile stress, the compression stress value and stress depth in the surface of the tempered glass reduce, with the result that the mechanical strength of the tempered glass is liable to deteriorate. Thus, the internal tensile stress is preferably 5 MPa or more, 10 MPa or more, particularly preferably 15 MPa or more.

When the tempered glass of this embodiment is used as a substrate or a cover glass, the tempered glass preferably has an unpolished surface, and the average surface roughness (Ra) of the unpolished surface is preferably 10 Å or less, 5 Å or less, particularly preferably 2 Å or less. Herein, the term “average surface roughness (Ra)” refers to a value obtained by a measurement method in accordance with SEMI D7-94 “FPD glass substrate surface roughness measurement method.” The theoretical strength of glass is very high intrinsically, but glass is often broken even by a stress far lower than the theoretical strength. This is because, in some steps after the glass is formed into a shape, such as a polishing step, a small defect called Griffith flaw is produced in the surfaces of the glass. Thus, when the surface of the tempered glass is not polished, the mechanical strength that glass intrinsically has is more unlikely to be impaired, and hence the tempered glass is more unlikely to break. In addition, when the surface of the tempered glass is not polished, the production cost of the tempered glass can be reduced, because the polishing step thereof can be eliminated. Moreover, when the entire surface of the tempered glass is unpolished (excluding a cutting surface), the tempered glass is much more unlikely to break. Besides, in order to prevent the tempered glass from breaking from its cutting surface, a chamfering process or the like may be applied to the cutting surface. Note that glass formation by an overflow down-draw method can yield an unpolished glass having a flat sheet shape and a good surface precision.

When the tempered glass of this embodiment is used as a substrate or a cover glass, the tempered glass has a thickness of preferably 3.0 mm or less, 1.5 mm or less, 1.0 mm or less, 0.7 mm or less, 0.5 mm or less, particularly preferably 0.3 mm or less. As the thickness becomes thinner, the tempered glass can have a lighter weight. Besides, the tempered glass of this embodiment has the advantage that it is unlikely to break even if it has a thin thickness. That is, as the thickness becomes thinner, the effect provided by the present invention is exhibited more significantly. Note that glass formation by an overflow down-draw method can yield a glass sheet having a good surface precision and can easily yield a glass sheet having a thin thickness.

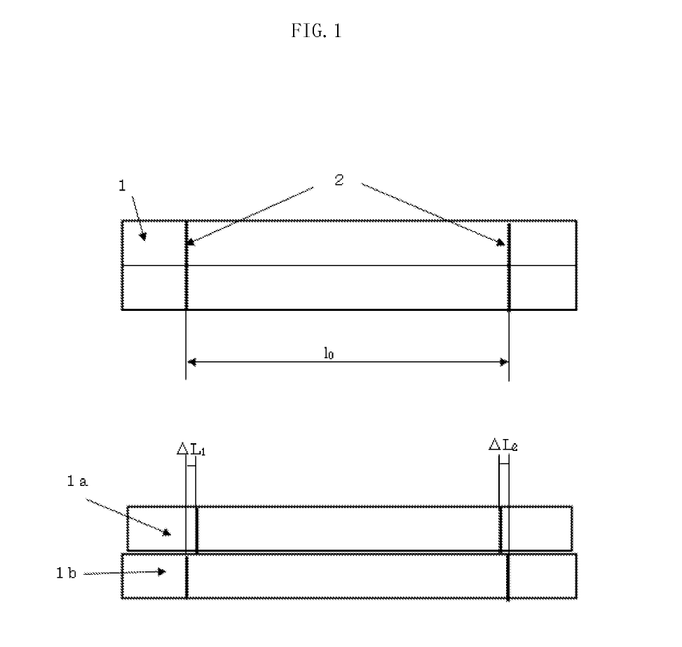

When the tempered glass of this embodiment is subjected to thermal treatment under the conditions of 500° C. for 1 hour, the tempered glass has a thermal shrinkage amount of preferably 250 ppm or less, 200 ppm or less, 180 ppm or less, 150 ppm or less, 130 ppm or less, 110 ppm or less, 80 ppm or less, particularly preferably 60 ppm or less. It is difficult to pattern a high-definition ITO film or the like on a tempered glass having too large a thermal shrinkage amount, and hence, for example, an operation failure of a touch sensor may be caused. Herein, the “thermal treatment” is calculated as described below. As illustrated in FIG. 1, linear markings are drawn at two sites on a tempered glass and a distance l₀ between the markings is then measured. Next, the tempered glass is folded vertically with respect to the markings, thereby dividing the tempered glass into two sample pieces. Thermal treatment is applied to only one of the sample pieces. The thermal treatment is carried out under the conditions of a temperature rise to 500° C. at +3° C./min, maintenance of the temperature of 500° C. for 1 hour, and a temperature fall to room temperature at −3° C./min. After that, the thermally treated sample piece and the non-thermally treated sample piece are lined up, followed by fixing of the both with an adhesive tape, and marking shifts ΔL₁ and ΔL₂ are measured. In the measurement, in the case where the positions of the markings of the thermally treated sample piece are located inside the positions of the markings of the non-thermally treated sample piece, ΔL₁ and ΔL₂ are represented as positive values, and a volume change amount is calculated by using Equation 2 described above.

A glass to be tempered according to an embodiment of the present invention comprises as a glass composition, in terms of mass %, 45 to 75% of SiO₂, 10 to 25% of Al₂O₂, 0 to 10% of B₂O₃, 0 to 8% of MgO, 0 to 20% of SrO+BaO, and 0 to 14% of Na₂O. The technical features (suitable component ranges, suitable characteristics, suitable aspects, and the like) of the glass to be tempered of this embodiment are, in principle, the same as the technical features of the tempered glass of the above-mentioned embodiment.

The glass to be tempered of this embodiment can be produced by loading glass raw materials blended so as to have a predetermined glass composition, into a continuous melting furnace, followed by melting under heating at 1,500 to 1,600° C., fining the resultant molten glass, forming the fined molten glass into a shape with a forming apparatus, and annealing the glass in an annealing apparatus.

A float method is preferably adopted as a forming method. The float method can be used to form a large amount of glass into a shape at low cost and to form a large glass easily. Further, when the float method is adopted, the above-mentioned cooling rate can be easily set, and hence the thermal shrinkage of the glass to be tempered can be easily reduced. In addition to the float method, various forming methods can be adopted. It is possible to adopt a forming method such as a down-draw method (e.g., an overflow down-draw method, a slot down method, or a re-draw method), a float method, a roll out method, or a press method. Particularly when the overflow down-draw method is adopted for glass formation, an unpolished glass having a good surface precision can be manufactured efficiently. When the press method is adopted for glass formation, a small glass can be manufactured efficiently.

The glass to be tempered of this embodiment is preferably cooled, in the temperature region from (annealing point+30° C.) to (strain point−70° C.), at an average cooling rate of 200° C./min or less, 150° C./min or less, 100° C./min or less, in particular, 80° C./min or less. If the glass to be tempered is cooled at too fast an average cooling rate, when the glass to be tempered is subjected to thermal treatment, the thermal shrinkage amount of the glass to be tempered becomes larger, and when the tempered glass is subjected to thermal treatment, the thermal shrinkage amount of the tempered glass becomes larger. Note that, from the viewpoint of production cost, the cooling is preferably performed successively after glass formation and is preferably performed in an annealing furnace.

When the glass to be tempered of this embodiment is subjected to ion exchange treatment in a KNO₃ molten salt at 460° C. for 10 hours, the resultant compression stress layer has a compression stress value of preferably 300 MPa or more, 500 MPa or more, particularly preferably 600 MPa or more, and the compression stress layer has a thickness of preferably 5 μm or more, 10 μm or more, particularly preferably 15 μm or more.

When the glass to be tempered of this embodiment is subjected to thermal treatment under the conditions of 500° C. for 1 hour after being subjected to tempering treatment (immersed in KNO₃ at 460° C. for 6 hours), the resultant tempered glass has a thermal shrinkage amount of preferably 250 ppm or less, 200 ppm or less, 180 ppm or less, 150 ppm or less, 130 ppm or less, 110 ppm or less, 80 ppm or less, particularly preferably 60 ppm or less. It is difficult to pattern a high-definition ITO film or the like on a tempered glass having too large a thermal shrinkage amount, and hence, for example, an operation failure of a touch sensor may be caused.

Note that the glass to be tempered may be cut and processed before tempering treatment, but from the viewpoint of production cost, the tempered glass is preferably cut and processed after tempering treatment.

### Example 1

Hereinafter, Examples of the present invention are described. Note that Examples below are merely illustrative. The present invention is by no means limited to Examples below.

Tables 1 to 5 show Examples of the present invention (Samples Nos. 1 to 33) and Comparative Example (Sample No. 34).

TABLE 1

| | | No. 1 | No. 2 | No. 3 | No. 4 | No. 5 | No. 6 | No. 7 |
|---|---|---|---|---|---|---|---|---|
| Glass | SiO₂ | 51.0 | 51.0 | 51.0 | 52.0 | 53.0 | 53.0 | 53.5 |
| composition | Al₂O₃ | 13.0 | 13.0 | 13.0 | 13.0 | 13.0 | 13.0 | 12.4 |
| (wt %) | B₂O₃ | — | — | — | — | — | — | — |
| | MgO | 0.1 | 0.1 | 0.1 | 0.1 | 0.1 | 0.1 | 0.1 |
| | CaO | 7.1 | 5.4 | 5.4 | 5.4 | 5.4 | 5.4 | 5.1 |
| | SrO | 11.9 | 13.6 | 11.9 | 9.1 | 9.1 | 9.1 | 11.2 |
| | BaO | 3.5 | 3.5 | 5.2 | 6.3 | 6.3 | 6.7 | 3.3 |
| | Li₂O | — | — | — | — | — | — | — |
| | Na₂O | 4.3 | 4.3 | 4.3 | 4.3 | 4.3 | 4.3 | 5.7 |
| | K₂O | 4.3 | 4.3 | 4.3 | 6.0 | 6.0 | 5.6 | 4.1 |
| | ZrO₂ | 4.6 | 4.6 | 4.6 | 3.6 | 2.6 | 2.6 | 4.4 |
| | Fe₂O₃ | 0.10 | 0.10 | 0.10 | 0.10 | 0.10 | 0.10 | 0.10 |
| | SnO₂ | — | 0.10 | — | 0.10 | — | — | — |
| | SO₃ | 0.10 | — | 0.10 | — | 0.10 | 0.10 | 0.10 |

| | | | | | | | |
|---|---|---|---|---|---|---|---|
| Thermal expansion coefficient | 80 | 80 | 80 | 83 | 83 | 83 | 81 |
| [×10⁻⁷/° C.] | | | | | | | |
| Density [g/cm³] | 2.83 | 2.84 | 2.84 | 2.80 | 2.79 | 2.80 | 2.79 |
| Strain point [° C.] | Not | 647 | 645 | 631 | 624 | 625 | 627 |
| | measured | | | | | | |
| Annealing point [° C.] | Not | 694 | 692 | 679 | 671 | 672 | 674 |
| | measured | | | | | | |
| Softening point [° C.] | Not | 891 | 892 | 881 | 874 | 875 | 875 |
| | measured | | | | | | |
| 10⁴ dPa · s [° C.] | 1,168 | 1,178 | 1,181 | 1,187 | 1,185 | 1,187 | 1,176 |
| 10³ dPa · s [° C.] | 1,313 | 1,326 | 1,331 | 1,347 | 1,348 | 1,350 | 1,333 |
| 10^{2.5} dPa · s [° C.] | 1,408 | 1,423 | 1,428 | 1,453 | 1,455 | 1,457 | 1,437 |
| Liquidus temperature [° C.] | 1,150 | 1,140 | 1,135 | 1,126 | 1,131 | 1,123 | 1,124 |
| Liquidus viscosity log₁₀η | 4.2 | 4.3 | 4.4 | 4.5 | 4.4 | 4.5 | 4.4 |
| [dPa · s] | | | | | | | |
| Compression stress value | Not | Not | Not | Not | Not | Not | Not |
| [MPa] | measured | measured | measured | measured | measured | measured | measured |
| Stress layer depth [μm] | Not | Not | Not | Not | Not | Not | Not |
| | measured | measured | measured | measured | measured | measured | measured |
| Compression stress value [MPa] | Not | Not | Not | Not | Not | Not | Not |
| (after thermal treatment | measured | measured | measured | measured | measured | measured | measured |
| at 540° C. for 20 minutes) | | | | | | | |
| Stress layer depth [μm] | Not | Not | Not | Not | Not | Not | Not |
| (after thermal treatment | measured | measured | measured | measured | measured | measured | measured |
| at 540° C. for 20 minutes) | | | | | | | |
| Thermal shrinkage amount | Not | Not | Not | Not | Not | Not | Not |
| (500° C.) [ppm] | measured | measured | measured | measured | measured | measured | measured |

TABLE 2

| | | No. 8 | No. 9 | No. 10 | No. 11 | No. 12 | No. 13 | No. 14 |
|---|---|---|---|---|---|---|---|---|
| Glass | SiO^{₂} | 51.0 | 50.8 | 51.0 | 52.8 | 52.5 | 51.0 | 51.0 |
| composition | Al₂O₃ | 13.0 | 13.0 | 13.0 | 13.0 | 13.0 | 13.0 | 13.0 |
| (wt %) | B₂O₃ | — | — | — | — | — | — | — |
| | MgO | 0.1 | 0.1 | 1.0 | 1.0 | 0.1 | 1.0 | 1.0 |
| | CaO | 5.4 | 5.4 | 4.5 | 6.5 | 5.4 | 6.5 | 4.5 |
| | SrO | 11.9 | 10.9 | 6.9 | 9.1 | 11.9 | 9.1 | 11.9 |
| | BaO | 3.5 | 4.5 | 8.5 | 4.3 | 3.5 | 4.3 | 3.5 |
| | Li₂O | — | — | — | — | — | — | — |
| | Na₂O | 6.0 | 5.8 | 5.0 | 5.0 | 6.0 | 5.0 | 5.0 |
| | K₂O | 4.3 | 4.6 | 5.3 | 5.3 | 4.3 | 5.3 | 5.3 |
| | ZrO₂ | 4.6 | 4.6 | 4.6 | 2.6 | 3.1 | 4.6 | 4.6 |
| | Fe₂O₃ | 0.10 | 0.20 | 0.10 | 0.30 | 0.10 | 0.15 | 0.10 |
| | SnO₂ | — | — | 0.10 | 0.10 | 0.10 | — | — |
| | SO₃ | 0.10 | 0.10 | — | — | — | 0.05 | 0.10 |

| | | | | | | | |
|---|---|---|---|---|---|---|---|
| Thermal expansion coefficient | 83 | 83 | 82 | 83 | 84 | 81 | 82 |
| [×10⁻⁷/° C.] | | | | | | | |
| Density [g/cm³] | 2.82 | 2.83 | 2.83 | 2.76 | 2.79 | 2.81 | 2.82 |
| Strain point [° C.] | 626 | 626 | 625 | 616 | 613 | 630 | 630 |
| Annealing point [° C.] | 672 | 673 | 672 | 662 | 659 | 677 | 677 |
| Softening point [° C.] | 867 | 870 | 881 | 863 | 855 | 875 | 878 |
| 10⁴ dPa · s [° C.] | 1,159 | 1,164 | 1,186 | 1,164 | 1,154 | 1,165 | 1,174 |
| 10³ dPa · s [° C.] | 1,309 | 1,317 | 1,342 | 1,321 | 1,311 | 1,314 | 1,326 |
| 10^{2.5} dPa · s [° C.] | 1,409 | 1,418 | 1,444 | 1,424 | 1,416 | 1,411 | 1,425 |
| Liquidus temperature [° C.] | 1,104 | 1,098 | 1,126 | 1,112 | 1,109 | 1,121 | 1,098 |
| Liquidus viscosity log₁₀η | 4.5 | 4.6 | 4.5 | 4.4 | 4.4 | 4.4 | 4.7 |
| [dPa · s] | | | | | | | |
| Compression stress value | 615 | Not | Not | Not | Not | Not | Not |
| [MPa] | | measured | measured | measured | measured | measured | measured |
| Stress layer depth [μm] | 10 | Not | Not | Not | Not | Not | Not |
| | | measured | measured | measured | measured | measured | measured |
| Compression stress value [MPa] | 570 | Not | Not | Not | Not | Not | Not |
| (after thermal treatment | | measured | measured | measured | measured | measured | measured |
| at 540° C. for 20 minutes) | | | | | | | |
| Stress layer depth [μm] | 10 | Not | Not | Not | Not | Not | Not |
| (after thermal treatment | | measured | measured | measured | measured | measured | measured |
| at 540° C. for 20 minutes) | | | | | | | |
| Thermal shrinkage amount | 60 | Not | Not | Not | Not | Not | Not |
| (500° C.) [ppm] | | measured | measured | measured | measured | measured | measured |

TABLE 3

| | | No. 15 | No. 16 | No. 17 | No. 18 | No. 19 | No. 20 | No. 21 |
|---|---|---|---|---|---|---|---|---|
| Glass | SiO₂ | 51.0 | 51.0 | 50.7 | 51.0 | 51.0 | 51.0 | 51.0 |
| composition | Al₂O₃ | 13.0 | 13.0 | 13.0 | 12.0 | 13.0 | 13.0 | 12.0 |
| (wt %) | B₂O₃ | — | — | — | — | — | — | — |
| | MgO | 1.0 | 0.1 | 0.1 | 0.1 | 0.1 | 1.0 | 0.1 |
| | CaO | 6.5 | 5.4 | 3.4 | 3.9 | 5.4 | 4.5 | 3.9 |
| | SrO | 6.9 | 9.1 | 9.1 | 11.4 | 9.9 | 9.1 | 8.4 |
| | BaO | 6.5 | 6.3 | 8.3 | 5.5 | 5.5 | 6.3 | 8.5 |
| | Li₂O | — | — | — | — | — | — | — |
| | Na₂O | 5.0 | 5.0 | 5.0 | 5.5 | 5.5 | 5.0 | 5.5 |
| | K₂O | 5.3 | 5.3 | 5.3 | 4.8 | 4.8 | 5.3 | 4.8 |
| | ZrO₂ | 4.6 | 4.6 | 4.6 | 5.6 | 4.6 | 4.6 | 5.6 |
| | Fe₂O₃ | 0.10 | 0.10 | 0.40 | 0.10 | 0.10 | 0.10 | 0.10 |
| | SnO₂ | — | — | — | — | — | — | — |
| | SO₃ | 0.10 | 0.10 | 0.10 | 0.10 | 0.10 | 0.10 | 0.10 |

| | | | | | | | |
|---|---|---|---|---|---|---|---|
| Thermal expansion coefficient | 82 | 82 | 82 | 83 | 83 | 82 | 82 |
| [×10⁻⁷/° C.] | | | | | | | |
| Density [g/cm³] | 2.81 | 2.83 | 2.84 | 2.85 | 2.83 | 2.82 | 2.86 |
| Strain point [° C] | 629 | 630 | 628 | 628 | 628 | 626 | 625 |
| Annealing point [° C.] | 675 | 677 | 676 | 675 | 674 | 674 | 672 |
| Softening point [° C.] | 876 | 879 | 884 | 876 | 873 | 880 | 877 |
| 10⁴ dPa · s [° C.] | 1,170 | 1,178 | 1,197 | 1,176 | 1,180 | 1,180 | 1,180 |
| 10³ dPa · s [° C.] | 1,321 | 1,331 | 1,358 | 1,328 | 1,336 | 1,336 | 1,335 |
| 10^{2.5} dPa · s [° C.] | 1,419 | 1,431 | 1,464 | 1,428 | 1,439 | 1,438 | 1,437 |
| Liquidus temperature [° C.] | 1,135 | 1,096 | 1,106 | 1,076 | 1,096 | 1,098 | 1,071 |
| Liquidus viscosity log₁₀η | 4.3 | 4.7 | 4.8 | 4.9 | 4.7 | 4.7 | 5.0 |
| [dPa · s] | | | | | | | |
| Compression stress value | Not | Not | Not | Not | Not | Not | Not |
| [MPa] | measured | measured | measured | measured | measured | measured | measured |
| Stress layer depth [μm] | Not | Not | Not | Not | Not | Not | Not |
| | measured | measured | measured | measured | measured | measured | measured |
| Compression stress value [MPa] | Not | Not | Not | Not | Not | Not | Not |
| (after thermal treatment | measured | measured | measured | measured | measured | measured | measured |
| at 540° C. for 20 minutes) | | | | | | | |
| Stress layer depth [μm] | Not | Not | Not | Not | Not | Not | Not |
| (after thermal treatment | measured | measured | measured | measured | measured | measured | measured |
| at 540° C. for 20 minutes) | | | | | | | |
| Thermal shrinkage amount | Not | Not | Not | Not | Not | Not | Not |
| (500° C.) [ppm] | measured | measured | measured | measured | measured | measured | measured |

TABLE 4

| | | No. 22 | No. 23 | No. 24 | No. 25 | No. 26 | No. 27 | No. 28 |
|---|---|---|---|---|---|---|---|---|
| Glass | SiO₂ | 50.0 | 50.0 | 53.0 | 50.5 | 53.0 | 53.6 | 51.0 |
| composition | Al₂O₃ | 12.0 | 12.0 | 13.0 | 12.5 | 13.0 | 14.9 | 13.0 |
| (wt %) | B₂O₃ | — | — | — | — | — | — | — |
| | MgO | 0.1 | 0.1 | 0.1 | 0.1 | 1.1 | 1.0 | 0.1 |
| | CaO | 3.9 | 3.9 | 5.4 | 3.9 | 7.7 | 7.8 | 6.5 |
| | SrO | 8.4 | 8.4 | 9.1 | 8.4 | 9.1 | 9.1 | 11.8 |
| | BaO | 9.5 | 8.5 | 6.3 | 8.5 | 3.0 | 3.0 | 2.5 |
| | Li₂O | — | — | — | — | — | — | — |
| | Na₂O | 5.5 | 5.5 | 5.0 | 5.5 | 5.0 | 5.0 | 5.0 |
| | K₂O | 4.8 | 5.8 | 5.3 | 4.8 | 5.3 | 5.3 | 5.3 |
| | ZrO₂ | 5.6 | 5.6 | 2.6 | 5.6 | 2.6 | 0.1 | 4.6 |
| | Fe₂O₃ | 0.10 | 0.10 | 0.10 | 0.10 | 0.10 | 0.10 | 0.10 |
| | SnO₂ | — | — | — | — | — | — | — |
| | SO₃ | 0.10 | 0.10 | 0.10 | 0.10 | 0.10 | 0.10 | 0.10 |

| | | | | | | | |
|---|---|---|---|---|---|---|---|
| Thermal expansion coefficient | 83 | 85 | 82 | 82 | 83 | 84 | 83 |
| [×10⁻⁷/° C.] | | | | | | | |
| Density [g/cm³] | 2.88 | 2.86 | 2.78 | 2.86 | 2.75 | 2.71 | 2.81 |
| Strain point [° C.] | 624 | 620 | 614 | 629 | 620 | 614 | 637 |
| Annealing point [° C.] | 671 | 667 | 661 | 676 | 665 | 660 | 683 |
| Softening point [° C.] | 874 | 871 | 864 | 882 | 862 | 858 | 877 |
| 10⁴ dPa · s [° C.] | 1,172 | 1,173 | 1,166 | 1,185 | 1,153 | 1,162 | 1,166 |
| 10³ dPa · s [° C.] | 1,325 | 1,327 | 1,330 | 1,340 | 1,306 | 1,324 | 1,314 |
| 10^{2.5} dPa · s [° C.] | 1,425 | 1,427 | 1,436 | 1,441 | 1,406 | 1,431 | 1,412 |
| Liquidus temperature [° C.] | 1,079 | 1,077 | 1,114 | 1,140 | 1,151 | 1,153 | 1,145 |
| Liquidus viscosity log₁₀η | 4.8 | 4.8 | 4.4 | 4.4 | 4.0 | 4.1 | 4.2 |
| [dPa · s] | | | | | | | |
| Compression stress value | Not | Not | Not | Not | Not | Not | Not |
| [MPa] | measured | measured | measured | measured | measured | measured | measured |
| Stress layer depth [μm] | Not | Not | Not | Not | Not | Not | Not |
| | measured | measured | measured | measured | measured | measured | measured |
| Compression stress value [MPa] | Not | Not | Not | Not | Not | Not | Not |
| (after thermal treatment | measured | measured | measured | measured | measured | measured | measured |
| at 540° C. for 20 minutes) | | | | | | | |
| Stress layer depth [μm] | Not | Not | Not | Not | Not | Not | Not |
| (after thermal treatment | measured | measured | measured | measured | measured | measured | measured |
| at 540° C. for 20 minutes) | | | | | | | |
| Thermal shrinkage amount | Not | Not | Not | Not | Not | Not | Not |
| (500° C.) [ppm] | measured | measured | measured | measured | measured | measured | measured |

TABLE 5

| | | No. 29 | No. 30 | No. 31 | No. 32 | No. 33 | No. 34 |
|---|---|---|---|---|---|---|---|
| Glass | SiO₂ | 53.5 | 51 | 49.1 | 50.1 | 50.6 | 58.1 |
| composition | Al₂O₃ | 12.4 | 13.0 | 13.0 | 13.0 | 13.0 | 13.0 |
| (wt %) | B₂O₃ | — | — | 1.9 | 0.9 | 0.4 | — |
| | MgO | 0.1 | 0.1 | 0.1 | 0.1 | 0.1 | 2.0 |
| | CaO | 5.1 | 5.4 | 5.4 | 5.4 | 5.4 | 2.0 |
| | SrO | 11.2 | 11.9 | 11.9 | 11.9 | 11.9 | — |
| | BaO | 3.3 | 3.5 | 3.5 | 3.5 | 3.5 | — |
| | Li₂O | — | — | — | — | — | 0.1 |
| | Na₂O | 5.7 | 6.0 | 6.0 | 6.0 | 6.0 | 14.5 |
| | K₂O | 4.1 | 4.3 | 4.3 | 4.3 | 4.3 | 5.5 |
| | ZrO₂ | 4.4 | 4.6 | 4.6 | 4.6 | 4.6 | 4.5 |
| | Fe₂O₃ | 0.01 | 0.01 | 0.01 | 0.01 | 0.01 | — |
| | SnO₂ | 0.19 | 0.19 | 0.19 | 0.19 | 0.19 | 0.3 |
| | SO₃ | — | — | — | — | — | — |

| | | | | | | |
|---|---|---|---|---|---|---|
| Thermal expansion coefficient | 81 | 83 | 84 | 84 | 84 | 102 |
| [×10⁻⁷/° C.] | | | | | | |
| Density [g/cm³] | 2.79 | 2.82 | 2.82 | 2.82 | 2.82 | 2.54 |
| Strain point [° C.] | 627 | 626 | 613 | 620 | 623 | 533 |
| Annealing point [° C.] | 674 | 672 | 656 | 665 | 669 | 576 |
| Softening point [° C.] | 875 | 867 | 839 | 854 | 861 | 793 |
| 10⁴ dPa · s [° C.] | 1,176 | 1,159 | 1,121 | 1,141 | 1,151 | 1,142 |
| 10³ dPa · s [° C.] | 1,333 | 1,309 | 1,269 | 1,290 | 1,300 | 1,319 |
| 10^{2.5} dPa · s [° C.] | 1,437 | 1,409 | 1,486 | 1,511 | 1,523 | 1,431 |
| Liquidus temperature [° C.] | 1,124 | 1,104 | 1,065 | 1,084 | 1,094 | 880 |
| Liquidus viscosity log₁₀η | 4.4 | 4.5 | 4.5 | 4.5 | 4.5 | 6.4 |
| [dPa · s] | | | | | | |
| Compression stress value | Not | Not | Not | Not | Not | 890 |
| [MPa] | measured | measured | measured | measured | measured | |
| Stress layer depth [μm] | Not | Not | Not | Not | Not | 22 |
| | measured | measured | measured | measured | measured | |
| Compression stress value [MPa] | Not | Not | Not | Not | Not | — |
| (after thermal treatment | measured | measured | measured | measured | measured | |
| at 540° C. for 20 minutes) | | | | | | |
| Stress layer depth [μm] | Not | Not | Not | Not | Not | — |
| (after thermal treatment | measured | measured | measured | measured | measured | |
| at 540° C. for 20 minutes) | | | | | | |
| Thermal shrinkage amount | Not | Not | Not | Not | Not | 270 |
| (500° C.) [ppm] | measured | measured | measured | measured | measured | |

Each of the samples in the tables was produced as described below. First, glass raw materials were blended so as to have glass compositions shown in the tables, and melted at 1,580° C. for 8 hours using a platinum pot. Next, the resultant molten glass was cast on a carbon plate and formed into a flat sheet shape. The resultant glass was evaluated for its various characteristics.

The thermal expansion coefficient is a value obtained through measurement of an average thermal expansion coefficient in the temperature range of 30 to 380° C. using a dilatometer.

The density is a value obtained through measurement by the well-known Archimedes method.

The strain point, the annealing point, and the softening point are values obtained through measurement based on a method described in ASTM C336.

The temperatures at viscosities at high temperature of 10^{4.0} dPa·s, 10^{3.0} dPa·s, and 10^{2.5} dPa·s are values obtained through measurement by a platinum sphere pull up method.

The liquidus temperature is a value obtained through measurement of a temperature at which crystals of glass are deposited after glass is pulverized and glass powder that passes through a standard 30-mesh sieve (sieve opening: 500 μm) and remains on a 50-mesh sieve (sieve opening: 300 μm) is placed in a platinum boat and then kept for 24 hours in a gradient heating furnace.

The liquidus viscosity is a value obtained through measurement of a viscosity of glass at the liquidus temperature by a platinum sphere pull up method.

Note that a non-tempered glass and a tempered glass have different glass compositions microscopically in their surface layers, but the glass compositions of the whole non-tempered glass and whole tempered glass are not substantially different. Thus, the values of characteristics such as thermal expansion coefficient, density, and viscosity are not substantially different between the non-tempered glass and tempered glass.

Both surfaces of Sample No. 8 were optically polished, and ion exchange treatment was then performed. The ion exchange treatment was performed by immersing each of the samples in a KNO₃ molten salt under the conditions of 460° C. for 6 hours. Next, the surfaces of Sample No. 8 were washed. After that, the number of interference fringes and each interval between the interference fringes were observed with a surface stress meter (manufactured by TOSHIBA CORPORATION, FSM-6000) to calculate the compression stress value and thickness of the compression stress layer. In the calculation, the refractive index of Sample No. 8 was 1.52, and the photoelastic constant thereof was 26 [(nm/cm)/MPa]. Further, Sample No. 8 to which the ion exchange treatment had been applied was treated under the conditions of a temperature rise to 540° C. at +5° C./min, maintenance of the temperature of 540° C. for 20 minutes, and a temperature fall to room temperature at −10° C./min. After that, the stress compression value and thickness of the compression stress layer were calculated once again.

Both surfaces of Sample No. 34 were optically polished, and ion exchange treatment was then performed. The ion exchange treatment was performed by immersing each of the samples in a KNO₃ molten salt under the conditions of 420° C. for 2 hours. Next, the surfaces of Sample No. 34 were washed. After that, the number of interference fringes and each interval between the interference fringes were observed with a surface stress meter (manufactured by TOSHIBA CORPORATION, FSM-6000) to calculate the compression stress value and thickness of the compression stress layer. In the calculation, the refractive index of Sample No. 8 was 1.52, and the photoelastic constant thereof was 28 [(nm/cm)/MPa]. Further, Sample No. 34 to which the ion exchange treatment had been applied was treated under the conditions of a temperature rise to 540° C. at +5° C./min, maintenance of the temperature of 540° C. for 20 minutes, and a temperature fall to room temperature at −10° C./min. After that, the stress compression value and thickness of the compression stress layer were calculated once again.

Next, glass materials were blended so that each of the glass compositions according to Sample Nos. 8 and 34 was achieved, and then the resultant glass batch was melted. After that, the resultant molten glass was formed into a glass having a flat sheet shape (a thickness of 0.7 mm) by a float method. In that case, temperature setting was performed so that the temperature in the vicinity of the inlet of a tin bath reached 1,200° C. and the temperature in the vicinity of the outlet thereof reached around 700° C. Subsequently, the glass was moved out from the tin bath and was transported through an annealing furnace. In that case, temperature setting was performed so that the temperature in the vicinity of the inlet of the annealing furnace reached about 700° C. and the temperature in the vicinity of the outlet thereof reached around 100° C. Next, a glass piece with a size of 30 mm in length, 160 mm in width, and 0.7 mm in thickness was cut out from the resultant glass and was used as a glass to be tempered. The thermal shrinkage amount (S) of the glass to be tempered was measured in accordance with the following procedure.

First, markings were vertically drawn at sites each located 20 to 40 mm inside from each edge of the strip-shaped sample piece (glass to be tempered), and the sample piece was then folded and divided horizontally. After the above-mentioned tempering treatment was applied to only one of the divided sample pieces, the tempered sample piece and the non-tempered sample piece were lined up, followed by fixing of the both with an adhesive tape, and marking shifts ΔL₁ and ΔL₂ were measured. In the measurement, in the case where the positions of the markings of the tempered sample piece were located inside the positions of the markings of the non-tempered sample piece, ΔL₁ and ΔL₂ were represented as positive values, and a volume change amount S1 was calculated by using Equation 2 described above. Subsequently, thermal treatment was applied only to the tempered glass. The thermal treatment was carried out under the conditions of a temperature rise to 500° C. at +3° C./min, maintenance of the temperature of 500° C. for 1 hour, and a temperature fall to room temperature at −3° C./min. After that, the thermally treated sample piece and the non-thermally treated (and non-tempered) sample piece were lined up, followed by fixing of the both with an adhesive tape, and marking shifts ΔL₁ and ΔL₂ were measured. In the measurement, in the case where the positions of the markings of the thermally treated sample piece were located inside the positions of the markings of the non-thermally treated sample piece, ΔL₁ and ΔL₂ were represented as positive values, and a volume change amount S2 was calculated by using Equation 2 described below. Finally, the thermal shrinkage amount of the glass to be tempered was calculated by using Equation 3.

As evident from Tables 1 to 5, each of Samples Nos. 1 to 33 has a strain point of 613° C. or more, and hence it is expected that, even if thermal treatment is applied at high temperature, its compression stress is unlikely to disappear and thermal shrinkage is unlikely to occur. Further, each of Samples Nos. 1 to 33 has a temperature at a viscosity at high temperature of 10^{2.5} dPa·s of 1,523° C. or less, thus being excellent in meltability. In addition, each of Samples Nos. 1 to 33 has a liquidus temperature of 1,153° C. or less and a liquidus viscosity of 10^{4.0} dPa·s or more, thus being excellent in denitrification resistance.

On the other hand, Sample No. 34 had a high liquidus viscosity but had a low strain point, and hence thermal treatment under the conditions of 540° C. for 20 minutes caused its compression stress layer to disappear completely and Sample No. 34 had a thermal shrinkage amount of 270 ppm after thermal treatment was performed under the conditions of 500° C. for 1 hour.

### INDUSTRIAL APPLICABILITY

As apparent from the foregoing description, the tempered glass of the present invention is suitable for applications in which a transparent conductive film having a high resolution, a high transmittance, and a low electrical resistance is formed, the applications including, for example, a cover glass for a touch panel display, a substrate for a solar cell (in particular, a substrate for a thin-film compound solar cell such as a CIS-based solar cell), and a substrate for a dye-sensitized solar cell. In addition, the tempered glass of the present invention is expected to find use in applications requiring a high mechanical strength, for example, a window glass, a substrate for a magnetic disk, a substrate for a flat panel display, a cover glass for a solid image pickup device, and tableware.

### REFERENCE SIGNS LIST

1 glass
1a non-tempered sample piece (non-thermally treated sample piece)
1b tempered sample piece (thermally treated sample piece) marking
2 marking

1. A tempered glass having a compression stress layer in a surface thereof, the tempered glass comprising as a glass composition, in terms of mass %, 45 to 75% of SiO₂, 10 to 25% of Al₂O₃, 0 to 10% of B₂O₃, 0 to 8% of MgO, 0 to 20% of SrO+BaO, and 0 to 14% of Na₂O.

2. A tempered glass having a compression stress layer in a surface thereof, the tempered glass comprising as a glass composition, in terms of mass %, 45 to 75% of SiO₂, 10 to 25% of Al₂O₃, 0 to 10% of B₂O₃, 0 to 4% of MgO, 0 to 20% of SrO+BaO, and 0 to 10% of Na₂O.

3. A tempered glass having a compression stress layer in a surface thereof, the tempered glass comprising as a glass composition, in terms of mass %, 45 to 63% of SiO₂, 10 to 25% of Al₂O₃, 0 to 10% of B₂O₃, 0 to 4% of MgO, 0.1 to 20% of SrO+BaO, and 0.1 to 10% of Na₂O.

4. A tempered glass having a compression stress layer in a surface thereof, the tempered glass comprising as a glass composition, in terms of mass %, 45 to 63% of SiO₂, 10 to 25% of Al₂O₃, 0 to 10% of B₂O₃, 0 to 4% of MgO, 0.1 to 20% of SrO+BaO, and 1 to 10% of Na₂O and having a mass ratio (MgO+CaO)/(SrO+BaO) of from 0.1 to 1.5.

5. A tempered glass having a compression stress layer in a surface thereof, the tempered glass comprising as a glass composition, in terms of mass %, 45 to 63% of SiO₂, 10 to 25% of Al₂O₃, 0 to 10% of B₂O₃, 0 to 3% of MgO, 0.1 to 15% of CaO, 0.1 to 13% of SrO, 0.1 to 20% of SrO+BaO, and 1 to 8% of Na₂O and having a mass ratio (MgO+CaO)/(SrO+BaO) of from 0.1 to 1.0.

6. A tempered glass having a compression stress layer in a surface thereof, the tempered glass comprising as a glass composition, in terms of mass %, 45 to 63% of SiO₂, 10 to 25% of Al₂O₃, 0 to 10% of B₂O₃, O to less than 2% of MgO, 2 to 15% of CaO, 5 to 13% of SrO, 0.1 to 8% of BaO, 5.1 to 20% of SrO+BaO, and 1 to 8% of Na₂O and having a mass ratio (MgO+CaO)/(SrO+BaO) of from 0.1 to 0.8.

7. A tempered glass having a compression stress layer in a surface thereof, the tempered glass comprising as a glass composition, in terms of mass %, 45 to 63% of SiO₂, 12 to 25% of Al₂O₃, 0 to 10% of B₂O₃, O to less than 2% of MgO, 2 to 15% of CaO, 8 to 13% of SrO, 2 to 8% of BaO, 10 to 20% of SrO+BaO, and 1 to 8% of Na₂O and having a mass ratio (MgO+CaO)/(SrO+BaO) of from 0.1 to 0.5.

8. The tempered glass according to any one of claims 1 to 7, wherein a compression stress value of the compression stress layer is 300 MPa or more, and a thickness of the compression stress layer is 5 μm or more.

9. The tempered glass according to any one of claims 1 to 7, wherein the tempered glass has an internal tensile stress of 50 MPa or less.

10. (canceled)

11. The tempered glass according to claim 1, wherein the tempered glass has a strain point of 550° C. or more.

12. The tempered glass according to claim 1, wherein the tempered glass has a temperature at a viscosity at high temperature of 10^{2.5} dPa·s of 1,550° C. or less.

13. The tempered glass according to claim 1, wherein the tempered glass has a liquidus temperature of 1,200° C. or less.

14. The tempered glass according to claim 1, wherein the tempered glass has a liquidus viscosity of 10^{3.0} dPa·s or more.

15. The tempered glass according to claim 1, wherein the tempered glass is used for a substrate for a solar cell.

16. The tempered glass according to claim 15, wherein the tempered glass is used for a substrate for a thin-film compound solar cell.

17. The tempered glass according to claim 1, wherein the tempered glass is used for a substrate for a display.

18. The tempered glass according to claim 1, wherein the tempered glass is formed into a flat sheet shape by a float method.

19. The tempered glass according to claim 1, wherein the tempered glass is manufactured by being cooled at an average cooling rate of 200° C./min or less in a temperature region from (annealing point+30° C.) to (strain point−70° C.).

20. A glass to be tempered, comprising as a glass composition, in terms of mass %, 45 to 75% of SiO₂, 10 to 25% of Al₂O₃, 0 to 10% of B₂O₃, 0 to 8% of MgO, 0 to 20% of SrO+BaO, and 0 to 14% of Na₂O.

21. The glass to be tempered according to claim 20, wherein the glass to be tempered has a thickness of 2 mm or less and has a thermal shrinkage amount of 250 ppm or less when the glass to be tempered is subjected to thermal treatment under conditions of 500° C. for 1 hour after being subjected to tempering treatment involving immersion in KNO₃ at 460° C. for 6 hours.
